(19) United States
(12) Patent Application Publication
(10) Pub. No.: US 2012/0265475 A1
(43) Pub. Date: Oct. 18, 2012

(54) Device for Testing a Charge System and Method of Providing and Using the Same

(75) Inventors: Tyler Gray, Gilbert, AZ (US); Dimitri Hochard, Scottsdale, AZ (US); Camron H. Vossberg, Tempe, AZ (US); Garrett Beauregard, Phoenix, AZ (US)

(73) Assignee: Electric Transportation Engineering Corporation, d/b/a ECOtality North America, Phoenix, AZ (US)

(21) Appl. No.: 13/396,113

(22) Filed: Feb. 14, 2012

Related U.S. Application Data
(60) Provisional application No. 61/476,093, filed on Apr. 15, 2011.

(51) Int. Cl. G01R 31/00

(52) U.S. Cl. 702/117

(57) ABSTRACT

In some embodiments, a device for testing a charge system and method of providing and using the same. Other embodiments of related devices and methods are also disclosed.

### CROSS-REFERENCE TO RELATED APPLICATIONS

This application claims the benefit of U.S. Provisional Application No. 61/476,093, filed Apr. 15, 2011. U.S. Provisional Application No. 61/476,093 is incorporated by reference herein.

### STATEMENT REGARDING FEDERALLY SPONSORED RESEARCH OR DEVELOPMENT

This invention was made with U.S. Government support under Contract No. DE-EE00002194 awarded by the Department of Energy. The Government has certain rights in this invention.

### FIELD OF THE INVENTION

This invention relates generally to devices for testing charge systems, and relates more particularly to such devices for testing charge systems for charging rechargeable energy storage systems of electric vehicles and methods of providing and using the same.

### DESCRIPTION OF THE BACKGROUND

Rechargeable energy storage systems of electric vehicles are conventionally charged with electric vehicle charging stations configured to provide electricity to the rechargeable energy storage systems; however, an improperly configured and/or malfunctioning electric vehicle charging station may pose considerable risk to not only an electric vehicle, but also an operator of the electric vehicle charging station as well. For example, an improperly configured and/or malfunctioning electric vehicle charging station providing an excessive quantity of electricity to a rechargeable energy storage system of an electric vehicle could potentially damage the electric vehicle due to overheating and/or explosion. Damage to the electric vehicle may be costly, and in some instances, may be irreparable. In the same example, the overheating and/or explosion can also place an operator of the electric vehicle charging station at risk of injury or death. Meanwhile, in another example, an improperly configured and/or malfunctioning electric vehicle charging station may also expose an operator to electric shock or electrocution. Consequently, determining that an electric vehicle charging station is configured and/or functioning properly can be imperative to safely operating the electric vehicle charging station. Still, without subjecting an electric vehicle charging station to realistic operating conditions (i.e., actually operating the electric vehicle charging station to provide electricity to a rechargeable energy storage system of an electric vehicle), it can be difficult to accurately determine that an electric vehicle charging station is, in fact, configured and/or functioning according to specification.

Accordingly, a need or potential for benefit exists for a device for testing a charge system of an electric vehicle that can emulate realistic operating conditions to ensure that the electric vehicle charging station is configured and/or functioning according to specification, without subjecting an electric vehicle to damage and/or unwittingly exposing an operator to dangerous conditions.

### BRIEF DESCRIPTION OF THE DRAWINGS

To facilitate further description of the embodiments, the following drawings are provided in which:

FIG. 1 illustrates a test device for testing a charge system, according to an embodiment;

FIG. 2 illustrates a transverse view of an electricity supply line, according to the embodiment of FIG. 1;

FIG. 3 illustrates a computer that is suitable for implementing an embodiment of the test device of FIG. 1;

FIG. 4 illustrates a representative block diagram of an example of the elements included in the circuit boards inside chassis of the computer of FIG. 3;

FIG. 5 illustrates a flow chart for an exemplary method of providing a test device for testing a charge system;

FIG. 6 illustrates a flow chart for an exemplary embodiment of a procedure for providing a test module configured to receive electricity from the charge system via an electricity supply line, according to the embodiment of FIG. 5;

FIG. 7 illustrates a flow chart for an exemplary embodiment of a procedure for providing a control module configured to provide a first signal to the charge system and to control the test module, according to the embodiment of FIG. 5; and

FIG. 8 illustrates a flow chart for an exemplary method 800 of testing a charge system.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein.

The terms “couple,” “coupled,” “couples,” “coupling,” and the like should be broadly understood and refer to connecting two or more elements or signals, electrically, mechanically and/or otherwise. Two or more electrical elements may be electrically coupled together, but not be mechanically or otherwise coupled together; two or more mechanical elements may be mechanically coupled together, but not be electrically or otherwise coupled together; two or more electrical elements may be mechanically coupled together, but not be electrically or otherwise coupled together. Coupling may be for any length of time, e.g., permanent or semi-permanent or only for an instant.

“Electrical coupling” and the like should be broadly understood and include coupling involving any electrical signal, whether a power signal, a data signal, and/or other types or combinations of electrical signals. “Mechanical coupling” and the like should be broadly understood and include mechanical coupling of all types.

The absence of the word “removably,” “removable,” and the like near the word “coupled,” and the like does not mean that the coupling, etc. in question is or is not removable.

As used herein, the term “electric grid” follows the conventionally understood definition of the term (e.g., any electrical network configured to deliver electricity from one or more suppliers (e.g., utility companies, etc.) to consumers). Accordingly, the term “electric grid” should be broadly understood to include one or more electrical networks of varying scale. For example, “electric grid” can include an electrical network defined by a geographical area (e.g., one or more continents, countries, states, municipalities, ZIP codes, regions, etc.) and/or defined by some other context (e.g., the electrical network of a local utility company, etc.).

### DETAILED DESCRIPTION OF EXAMPLES OF EMBODIMENTS

Some embodiments include a test device for testing a charge system. The charge system can be configured to provide electricity to charge a rechargeable energy storage system of an electric vehicle via an electric supply line. Meanwhile, the charge system can comprise a residual current device. The test device comprises a test module configured to receive the electricity from the charge system via the electric supply line and a control module configured to provide a first signal to the charge system and to control the test module. The test module is configured to be electrically coupled to the charge system via the electric supply line. In many embodiments, the first signal can be configured to instruct the charge system to provide the electricity to the test module. The test module can be configured to apply a first electric resistance to the electricity to induce a first amount of electric current leakage in the test device while the charge system provides the electricity to the test module. Likewise, the test module can be configured to apply a second electric resistance to the electricity to induce a second amount of electric current leakage in the test device while the charge system provides the electricity to the test module. The second amount of electric current leakage can exceed the first amount of electric current leakage. The control module can be configured to control when the test module applies the first resistance and the second resistance to test the residual current device. The test device can be configured to emulate the rechargeable energy storage system of the electric vehicle.

Various embodiments include a method of providing a test device for testing a charge system. The charge system can be configured to provide electricity to charge a rechargeable energy storage system of an electric vehicle via an electric supply line. Meanwhile, the charge system can comprise a residual current device. The method can comprise: providing a test module configured to receive the electricity from the charge system via the electric supply line; and providing a control module configured to provide a first signal to the charge system and to control the test module. The test module is configured to be electrically coupled to the charge system via the electric supply line. In many embodiments, the first signal can be configured to instruct the charge system to provide the electricity to the test module. The test module can be configured to apply a first electric resistance to the electricity to induce a first amount of electric current leakage in the test device while the charge system provides the electricity to the test module. Likewise, the test module can be configured to apply a second electric resistance to the electricity to induce a second amount of electric current leakage in the test device while the charge system provides the electricity to the test module. The second amount of electric current leakage can exceed the first amount of electric current leakage. The control module can be configured to control when the test module applies the first resistance and the second resistance to test the residual current device. The test device can be configured to emulate the rechargeable energy storage system of the electric vehicle.

Further embodiments include a method of testing a charge system. The charge system can be configured to provide electricity to charge a rechargeable energy storage system of an electric vehicle via an electric supply line. Meanwhile, the charge system can comprise a residual current device. The method can comprise: electrically coupling the electric supply line to a test device, the test device being configured to receive the electricity from the charge system via the electric supply line and being configured to emulate the rechargeable energy storage system of the electric vehicle; providing a first signal from the test device to the charge system to instruct the charge system to provide the electricity to the test device; after providing the first signal, receiving the electricity from the charge system at the test device; determining when to apply a first electric resistance to the electricity at the test device to induce a first amount of electric current leakage in the test device while the test device receives the electricity; applying the first electric resistance to the electricity at the test device to induce the first amount of electric current leakage in the test device while the test device receives the electricity; determining when to apply a second electric resistance to the electricity at the test device to induce a second amount of electric current leakage in the test device while the test device receives the electricity, the second amount of electric current leakage exceeding the first amount of electric current leakage; and applying the second electric resistance to the electricity at the test device to induce the second amount of electric current leakage in the test device while the test device receives the electricity.

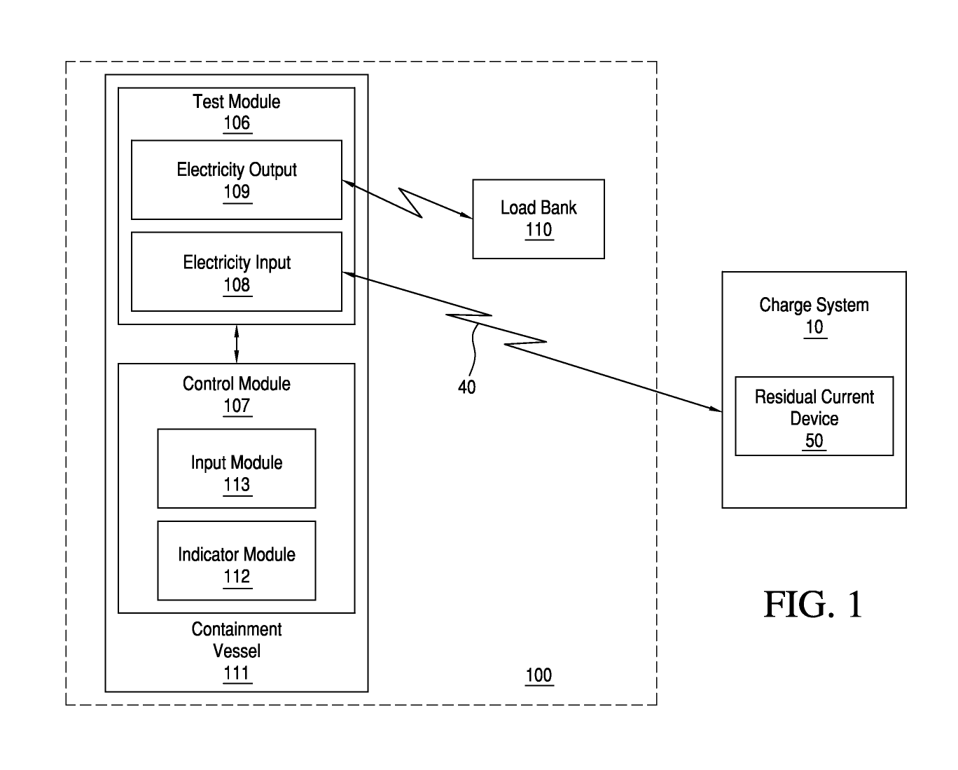

Turning to the drawings, FIG. 1 illustrates test device 100 for testing charge system 10, according to an embodiment. Test device 100 is merely exemplary and is not limited to the embodiments presented herein. Test device 100 can be employed in many different embodiments or examples not specifically depicted or described herein.

Charge system 10 can comprise an electric vehicle charging station; accordingly, charge system 10 can be configured to provide electricity to charge a rechargeable energy storage system of an electric vehicle. Test device 100 can be configured to emulate the rechargeable energy storage system of the electric vehicle and to test charge system 10. In many embodiments, test device 100 can be configured to test charge system 10 when charge system 10 is being manufactured and/or when charge system 10 is being installed for use to determine whether charge system 10 is operating according to specification and/or to diagnose whether charge system 10 is malfunctioning. The specification can be a specification established by one or more of the manufacturer of charge system 10, Underwriter's Laboratory, Incorporated, and/or the Society of Automotive Engineers (SAE).

Charge system 10 can comprise a terminal block (e.g., a screw terminal), control circuitry comprising a controlling circuit board (e.g., an electric vehicle supply equipment circuit board) and a control circuitry ground line, a metal enfoldment (e.g., an encasement and/or chassis of charge system 10), an electric grid line comprising a grid ground line, and a contactor. The terminal block can be configured to be electrically coupled to the control circuitry and/or the controlling circuit board, the electric grid line, and electric supply line 40, described below. The control circuitry and/or the controlling circuit board can be configured to operate and control charge system 10. For example, the controlling circuit board can control the contactor to determine when the contactor of charge system 10 permits the electricity to be provided to electric supply line 40, and when the contactor of charge system 10 does not permit the electricity to be provided to electric supply line 40. The electric grid line can be configured to be electrically coupled to an electric grid and to supply charge system 10 with electricity from the electric grid.

In some embodiments, charge system 10 can comprise an electric vehicle supply equipment (e.g., a device for providing electricity to the rechargeable energy storage system of the electric vehicle). In other embodiments, charge system 10 can comprise an industrial electric charger (e.g., an on-board AC electric charger, a off-board DC electric charger). In still other embodiments, charge system 10 can be configured to transfer electricity to a rechargeable energy storage system of the at least one electric vehicle via electrical induction. Charge system 10 can comprise either of a stand-alone unit or a wall-mounted unit. Likewise, charge system 10 can be configured for private and/or public use.

In various embodiments, the electric vehicle supply equipment can comprise a level 1 electric vehicle supply equipment, a level 2 electric vehicle supply equipment, and/or a level 3 electric vehicle supply equipment. The level 1 electric vehicle supply equipment can comprise either of a level 1 alternating current (AC) electric vehicle supply equipment or a level 1 direct current (DC) electric vehicle supply equipment. Meanwhile, the level 2 electric vehicle supply equipment can comprise either of a level 2 AC electric vehicle supply equipment or a level 2 DC electric vehicle supply equipment. Furthermore, the level 3 electric vehicle supply equipment can comprise either of a level 3 AC electric vehicle supply equipment or a level 3 DC electric vehicle supply equipment. In some embodiments, the level 2 electric vehicle supply equipment and/or the level 3 electric vehicle supply equipment can also be referred to as a fast charger. In many embodiments, the electric vehicle supply equipment can make available electricity comprising a maximum electric current of 30 amperes (A) or 48 A. When the maximum electric current of the electric vehicle supply equipment comprises 30 A, the electric vehicle supply equipment can be configured to make available electricity comprising an electric current of one or more of 12 A, 16 A, or 24 A. When the maximum electric current of the electric vehicle supply equipment comprises 48 A, the electric vehicle supply equipment can be configured to make available electricity comprising an electric current of one or more of 12 A, 16 A, 24 A, or 30 A.

For example, the level 1 AC electric vehicle supply equipment can make available electricity comprising an electric voltage of approximately 120 volts (V) and an electric current: greater than or equal to approximately 0 amperes (A) and less than or equal to approximately 12 A AC, when employing a 15 A breaker, or (b) greater than or equal to approximately 0 A and less than or equal to approximately 16 A AC, when employing a 20 A breaker. Accordingly, the level 1 electric vehicle supply equipment can comprise a standard grounded domestic electrical outlet. Meanwhile, the level 2 AC electric vehicle supply equipment can make available electricity comprising an electric voltage greater than or equal to approximately 208 V and less than or equal to approximately 240 V and an electric current greater than or equal to approximately 0 A and less than or equal to approximately 80 A AC. Furthermore, a level 3 electric vehicle supply equipment can make available electricity comprising an electric voltage greater than or equal to approximately 208 V and an electric current greater than or equal to approximately 80 A AC (e.g., 240 V AC (single phase), 208 V AC (triple phase), 480 V AC (triple phase). In some embodiments, the electric voltages for the level 1 electric vehicle supply equipment, the level 2 electric vehicle supply equipment, and/or the level 3 electric vehicle supply equipment can be within plus or minus (±) ten percent (%) tolerances of the electric voltages provided above.

In other examples, the level 1 DC electric vehicle supply equipment can provide electric power greater than or equal to approximately 0 kiloWatts (kW) and less than or equal to approximately 19 kW. Meanwhile, the level 2 DC electric vehicle supply equipment can provide electric power greater than or equal to approximately 19 kW and less than or equal to approximately 90 kW. Furthermore, level 3 electric vehicle supply equipment can provide electric power greater than or equal to approximately 90 kW. In some embodiments, the term fast charger can refer to an electric vehicle supply equipment providing electricity comprising an electric voltage between approximately 300 V-500 V and an electric current between approximately 100 A-400 A DC.

The industrial electric charger (e.g., the on-board AC electric charger, the off-board DC electric charger) can provide electric power greater than or equal to approximately 3 kW and less than or equal to approximately 33 kW. The off-board DC electric charger can provide electricity comprising an electric voltage greater than or equal to approximately 18 V DC and less than or equal to approximately 120 V DC.

Meanwhile, the rechargeable energy storage system can comprise a device configured to store electricity for the electric vehicle. In the same or different embodiments, the rechargeable energy storage system can comprise (a) one or more batteries and/or one or more fuel cells, (b) one or more capacitive energy storage systems (e.g., super capacitors such as electric double-layer capacitors), and/or (c) one or more inertial (e.g., flywheel) energy storage systems. In many embodiments, the one or more batteries can comprise one or more rechargeable (e.g., traction) and/or non-rechargeable batteries. For example, the one or more batteries can comprise one or more of a lead-acid battery, a valve regulated lead acid (VRLA) battery such as a gel battery and/or an absorbed glass mat (AGM) battery, a nickel-cadmium (NiCd) battery, a nickel-zinc (NiZn) battery, a nickel metal hydride (NiMH) battery, a zebra (e.g., molten chloroaluminate (NaAlCl₄)) and/or a lithium (e.g., lithium-ion (Li-ion)) battery. In some embodiments, where the rechargeable energy storage system comprises more than one battery, the batteries can all comprise the same type of battery. In other embodiments, where the rechargeable energy storage system comprises more than one battery, the batteries can comprise at least two types of batteries. In many embodiments, the at least one fuel cell can comprise at least one hydrogen fuel cell.

Furthermore, the electric vehicle can comprise one of a car, a truck, a motorcycle, a bicycle, a scooter, a boat, a train, an aircraft, an airport ground support equipment, a material handling equipment (e.g., a fork-lift), etc. In the same or different embodiments, electric vehicle can comprise one of a full electric vehicle or any other grid-connected vehicle.

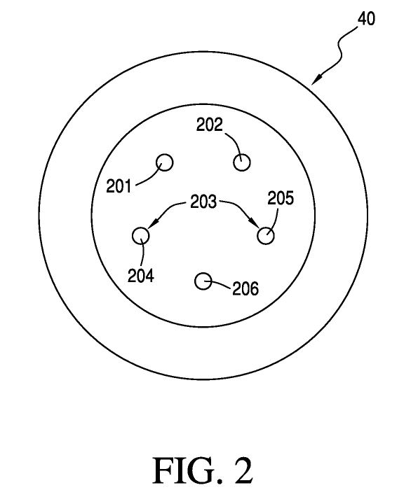

In many embodiments, charge system 10 can be configured to provide the electricity to charge the rechargeable energy storage system of the electric vehicle via electric supply line 40. FIG. 2 illustrates a transverse view of electric supply line 40, according to the embodiment of FIG. 1.

Skipping ahead to FIG. 2, in some embodiments, electric supply line 40 (FIG. 1) can comprise an electrical connector (e.g., a SAE J1772 electrical connector). The electrical connector can comprise a clamping mechanism configured to secure the electrical connector to an electricity input (e.g., electricity input 108, as described below). Electric supply line 40 and/or the electrical connector can comprise pilot line 201, proximity line 202, a pair of electric lines 203 comprising supply line 204 and supply/neutral line 205, and/or ground line 206.

Pilot line 201 can be configured to transmit a pilot flow of electricity (e.g., approximately −12 V of DC (VDC) to approximately 12 VDC) from (a) charge system 10 to (b) test device 100 and/or test module 106, when electric supply line is electrically coupled with test module 106 (FIG. 1), described below. Pilot line 201 can be configured to transmit a first signal and/or a second signal to charge system 10, as described in detail below with respect to control module 107. Control module 107 (FIG. 1) can provide the first signal and/or the second signal that under ordinary operation (e.g., non-testing operation) of charge system 10 would be provided by the electric vehicle and/or the rechargeable energy storage system. In many embodiments, the electrical properties (e.g., voltage and/or current) of the pilot flow of electricity can be defined according to the specifications of the SAE J1772 electrical connector.

Proximity line 202 can be configured to transmit a clamping mechanism signal from test device 100 to charge system 10 indicating that the clamping mechanism of the electrical connector of electric supply line 40 (FIG. 1) is engaged to secure the electrical connector to the electricity input of test device 100 when the electrical connector is coupled with the electricity input (e.g., electricity input 108, as described below) and when the clamping mechanism is engaged to secure the electrical connector to the electricity input. In some embodiments, where the clamping mechanism of the electrical connector of electric supply line 40 (FIG. 1) is omitted and/or inoperable, proximity line 202 can be omitted and/or inoperable.

Electric lines 203 (e.g., supply line 204 and supply/neutral line 205) can be configured to transmit the electricity from charge system 10 to the rechargeable energy storage system of the electric vehicle and/or test module 106 (FIG. 1), described below. Supply/neutral line 205 can be configured as either of a second electric line (e.g., when electric lines 203 are configured for a split-phase electric system) or a neutral electric line (e.g., when electric lines 203 are configured for a line-to-neutral electric system). Meanwhile, ground line 206 can be configured to electrically ground electric supply line 40 and/or electric lines 203. The functionality of electric lines 203 (e.g., supply line 204 and supply/neutral line 205) and ground line 206 and their respective interconnections is well known to those of ordinary skill in the art and requires no further discussion here. In some embodiments, the electricity transmitted by electric lines 203 (e.g., 240 VAC or 120 VAC) from charge system 10 to the rechargeable energy storage system of the electric vehicle and/or test module 106 (FIG. 1) can be used not only for testing/diagnostic purposes but also to electrically power test device 100 for operational purposes (e.g., by converting the electricity from 240 VAC or 120 VAC to VDC).

Referring now back to FIG. 1, charge system 10 can comprise residual current device 50 (e.g., a ground fault circuit interrupter). Residual current device 50 can be electrically coupled to electric supply line 40. Residual current device 50 can be configured to prevent and/or interrupt any electricity being provided to the rechargeable energy storage system of the electric vehicle (e.g., by interrupting a flow of electricity to electric supply line 40) in the event that residual current device 50 detects an imbalance in an electric current of the electricity (e.g., a leakage current) when the electric current is at supply line 204 (FIG. 2) versus when the electric current is at supply/neutral line 205 (FIG. 2). In many embodiments, residual current device 50 can be configured to interrupt the electricity when the imbalance in the electric current (e.g., the leakage current) is greater than or equal to approximately 4 milliamperes (mA) and/or is less than or equal to approximately 6 mA. In other embodiments, residual current device 50 can be configured to interrupt the electricity when the imbalance in the electric current (e.g., the leakage current) is greater than or equal to approximately 10 mA and/or is less than or equal to approximately 300 mA.

Referring again to FIG. 1, test device 100 comprises test module 106 and control module 107. Test module 106 is configured to receive the electricity from charge system 10 via electric supply line 40. Test module 106 is configured to be electrically coupled to charge system 10 via electric supply line 40. Test module 106 can comprise a test module power supply configured to transform the electricity from charge system 10 from 240 VAC or 120 VAC to a VDC compatible with device test device 100 in order to operate test device 100.

Meanwhile, control module 107 is configured to control test module 106. Accordingly, in many embodiments, control module 107 can be configured to communicate with test module 106. In some embodiments, control module 107 can comprise a first circuit board (e.g., an electric vehicle supply equipment circuit board, similar or identical to the controlling circuit board of charge system 10) and/or a second circuit board (e.g., a supplemental electronic vehicle supply equipment circuit board). The first circuit board can be configured to operate control module 107 and/or test device 100. The second circuit board can be configured to operate input module 113, described below. In some embodiments, the first circuit board can be configured both to operate control module 107 and/or test device 100 as well as to operate input module 113.

Referring again to FIG. 1, in some embodiments, test module 106 can comprise electricity input 108. Electricity input 108 can comprise an electrical receptacle for a SAE J1772 electrical connector, or the like. Accordingly, the electrical receptacle can be configured to receive the SAE J1772 electrical connector of electric supply line 40 to electrically couple test module 106 to charge system 10 via electric supply line 40.

In many embodiments, control module 107 can be configured to provide the first signal and/or the second signal to charge system 10, introduced above with respect to pilot line 201 (FIG. 2). The first signal can be configured to instruct charge system 10 to provide the electricity to test module 106 (i.e., it can cause charge system 10 to close the contactor of charge system 10). The second signal can be configured to notify charge system 10 that test module 106 is electrically coupled to charge system 10 via electric supply line 40. In these embodiments, however, charge system 10 does not close the contactor of charge system 10 until after receiving both the first and second signals. Accordingly, control module 107 can be configured to provide the second signal to charge system 10 before providing the first signal to charge system 10. In many embodiments, control module 107 can be configured to provide the first signal to charge system 10 by applying a first pilot line electric resistance to pilot line 201 (e.g., reducing the pilot flow of electricity from 12 VDC, or 9 VDC if applicable, to 6 VDC) and/or to provide the second signal to charge system 10 by applying a second pilot line electric resistance to pilot line 201 (e.g., reducing the pilot flow of electricity from 12 VDC to 9 VDC).

Referring again to FIG. 1, in various embodiments, test module 106 can comprise electricity output 109. Electricity output 109 can comprise an electrical receptacle for a National Electrical Manufacturers Association (NEMA) 14-50 electrical connector.

Referring again to FIG. 1, in some embodiments, test device 100 can comprise load bank 110. Load bank 110 can be configured to simulate an electric load of the rechargeable energy storage system of the electric vehicle. The electric load can be less than or equal to approximately 32 A and/or can be less than or equal to approximately 19.2 kiloWatts (kW). In some embodiments, load bank 110 can be part of test module 106 or can be separate from test module 106.

Test module 106 can be configured to apply a first leakage current electric resistance to the electricity received via electric supply line 40 from charge system 10 to induce a first amount of electric current leakage in test device 100 (e.g., across supply line 204 (FIG. 2) and ground line 206 (FIG. 2)) while charge system 10 provides the electricity to test module 106. In the same or different embodiments, test module 106 can be configured to apply a second leakage current electric resistance to the electricity received via electric supply line 40 from charge system 10 to induce a second amount of electric current leakage in test device 100 (e.g., across supply line 204 and ground line 206) while charge system 10 provides the electricity to test module 106. The second amount of electric current leakage can exceed the first amount of electric current leakage. In the same or different embodiments, the first amount of electric current leakage can be insufficient to activate residual current device 50, and the second amount of electric current leakage can be sufficient to activate residual current device 50. Accordingly, test module 106 can be configured to test that residual current device 50 is operating according to specification (e.g., it interrupts/prevents any electricity from being provided to electric supply line 40 when the electric current leakage exceeds a particular amount of electric current leakage). In various embodiments, test module 106 can be configured to test residual current device 50 when charge system 10 is being installed.

Likewise, test module 106 can be configured to test one or more of pilot line 201 (FIG. 2), proximity line 202 (FIG. 2), electric lines 203 (FIG. 2), and/or ground line 206 (FIG. 2), as applicable, while charge system 10 provides the electricity to test module 106. In various embodiments, test module 106 can be configured to test one or more of pilot line 201 (FIG. 2), proximity line 202 (FIG. 2), electric lines 203 (FIG. 2), and/or ground line 206 (FIG. 2) when charge system 10 is being installed.

Furthermore, test module 106 can be configured to be electrically coupled with load bank 110 via electricity output 109. Meanwhile, test module 106 can be configured to apply the electric load to charge system 10 to test if charge system 10 can support the electric load. In these embodiments, test module 106 can comprise a contactor configured to regulate when the electric load is applied to charge system 10. In various embodiments, test module 106 can be configured to test if charge system 10 can support the electric load during or after the manufacturing process for charge system 10 (e.g., during a quality assurance test for charge system 10).

In various embodiments, control module 107 can be configured to control: (a) when test module 106 applies the first leakage current electric resistance and the second leakage current electric resistance to test residual current device 50, (b) when test module 106 tests pilot line 201 (FIG. 2), proximity line 202 (FIG. 2), electric lines 203 (FIG. 2), and/or ground line 206 (FIG. 2), as applicable, and (c) when test module 106 applies the electric load to charge system 10 (e.g., by controlling the contactor of test module 106) in order to test whether charge system 10 can support the electric load. In many embodiments, by using input module 113, as described below, a user can determine when control module 107 causes test module 106 to run one or more of the above tests.

Referring again to FIG. 1, control module 107 can be configured to communicate with input module 113. Input module 113 can be configured to operate control module 107. In many embodiments, control module 107 can comprise input module 113 (e.g., a control panel), and/or input module 113 can be part of control module 107. In the same or different embodiments, input module 113 can be separate from (a) test device 100 and/or (b) control module 117, and/or input module 113 can comprise an operator computer system and/or an application programmable interface. For example, control module 107 can be configured to operate via the control panel, the operator computer system, and/or the application programmable interface (e.g., via cloud computing). Accordingly, the application programmable interface, the computer system and/or one or more cloud computer systems can be in communication with each other. For example, where control module 107 operates via the application programmable interface, the application programmable interface can be operated (e.g., in the capacity of an interface only) at one or more processors and/or stored at one or more memory storage modules of the operator computer system while the remaining functional aspects of the application programmable interface are operable at one or more processors and/or storable at one or more memory storage modules of the cloud computer system(s). Further, in some embodiments, the control panel can operate control module 107 while the operator computer system and/or the application programmable interface merely collects test data from test device 100. In other embodiments, the operator computer system and/or the application programmable interface can both operate control module 107 and collect test data from test device 100.

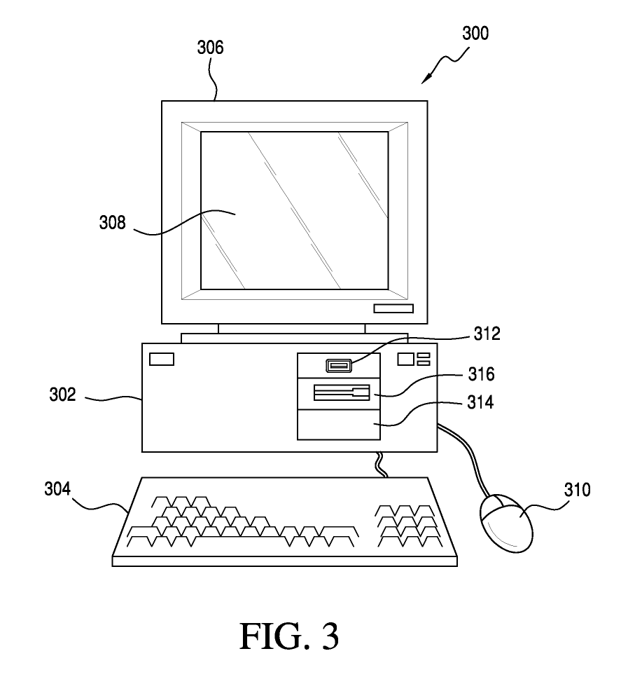

In the same or different embodiments, the operator computer system and/or the cloud computer system(s) can be similar or identical to computer system 300 (FIG. 3), as described below. An exemplary operator computer system can comprise a desktop computer system, a laptop computer system, and/or any suitable mobile computer system, such as, for example, a tablet computer system, and/or a smart phone, etc. Accordingly, in many examples, when input module 113 comprises the operator computer system and/or the application programmable interface, the operator computer system and/or the application programmable interface can be separate from control module 107 but at least part of the operator computer system and/or the application programmable interface can be located and/or operated proximate to control module 107. In the same or other examples, when input module 113 comprises the operator computer system and/or the application programmable interface, at least part of the operator computer system and/or the application programmable interface can be located remotely from control module 107. For example, when input module 113 comprises the operator computer system, a locally operated part of the operator computer system can operate control module 107 while a remote part of the operator computer system receives test data.

In some embodiments, test device 100 can comprise a data port. The data port can be configured to communicate with input module 113 (e.g., when input module 113 comprises the operator computer system and/or the application programmable interface). The data port can be configured to receive a data cable (e.g., an International Protection 68 Registered Jack 45 (IP68 RJ45) cable, a Universal Serial Bus (USB) cable, and/or any other suitable data cable) to communicate with input module 113. In other embodiments, test device 100 can comprise a wireless communication device configured to communicate with input module 113 (e.g., when input module 113 comprises the operator computer system and/or the application programmable interface). The wireless communication device can be configured to communicate with input module 113 via any suitable wireless networking protocol. Exemplary wireless networking protocols can comprise wireless personal area network communication (e.g., Bluetooth, Zigbee, Wireless Universal Serial Bus (USB), Z-Wave, etc.), wireless local area network communication (e.g., Institute of Electrical and Electronic Engineers (IEEE) 802.11), wireless wide area network communication (e.g., IEEE 802.11), and/or wireless cellular network communication (e.g., Global System for Mobile Communications (GSM), General Packet Radio Service (GPRS), Code Division Multiple Access (CDMA), Evolution-Data Optimized (EV-DO), Enhanced Data Rates for GSM Evolution (EDGE), 3GSM, Digital Enhanced Cordless Telecommunications (DECT), Digital AMPS (IS-136/Time Division Multiple Access (TDMA)), Integrated Digital Enhanced Network (iDEN), etc.).

Input module 113 can comprise a first input mechanism, a second input mechanism, a third input mechanism, a fourth input mechanism, and/or a fifth mechanism. The first input mechanism, the second input mechanism, the third input mechanism, the fourth input mechanism, and/or the fifth mechanism can each comprise a different input of a graphical user interface when input module 113 comprises the operator computer system and/or the application programmable interface.

In other embodiments, such as when input module comprises a control panel, each input mechanism can each comprise a different toggle switch. For example, the first input mechanism can comprise a first setting (e.g., auto) and a second setting (e.g., manual). When the first input mechanism is set to the first setting (e.g., auto), control module 107 can be configured to automatically cause test module 106 to test one or more of pilot line 201 (FIG. 2), proximity line 202 (FIG. 2), electric lines 203 (FIG. 2), and/or ground line 206 (FIG. 2), as applicable, while charge system 10 provides the electricity to test module 106. Meanwhile, after testing one or more of pilot line 201 (FIG. 2), proximity line 202 (FIG. 2), electric lines 203 (FIG. 2), and/or ground line 206 (FIG. 2), control module 107 can be configured to automatically cause test module 106 to apply the electric load of load bank 110 to charge system 10 to test if charge system 10 can support the electric load.

When the first input mechanism is set to the second setting (e.g., manual), control module 107 can be configured to permit manual operation of test device 100. Specifically, setting the first input mechanism to the second setting can permit the user to operate the fourth input mechanism and the fifth mechanism, as explained below. In many embodiments, the fourth input mechanism and/or the fifth mechanism can be configured such that one or both will not operate (e.g., operate properly) when the first input mechanism is set to the first setting.

The second input mechanism can comprise a first setting (e.g., connect) and a second setting (e.g., disconnect). When the second input mechanism is set to the first setting (e.g., connect), control module 107 can be configured to provide the second signal to charge system 10 by applying the second pilot line electric resistance to pilot line 201 when the pilot line is transmitting the pilot flow of electricity. Consequently, charge system 100 can receive the first signal, notifying charge system 10 that test module 106 is electrically coupled to charge system 10 via electric supply line 40. Meanwhile, when the second input mechanism is set to the second setting (e.g., disconnect), control module 107 can be configured such that control module 107 does not provide the second signal to charge system 10. Accordingly, charge system 100 remains configured as if test module 106 is not electrically coupled to charge system 10 via electric supply line 40.

The third input mechanism can comprise a first setting (e.g., charge) and a second setting (e.g., idle). When the third input mechanism is set to the first setting (e.g., charge), control module 107 can be configured to provide the first signal to charge system 10 by applying the first pilot line electric resistance to pilot line 201 when the pilot line is transmitting the pilot flow of electricity. Consequently, charge system 100 can receive the first signal and provide electricity to test module 106. Meanwhile, when the third input mechanism is set to the second setting (e.g., idle), control module 107 can be configured such that control module 107 does not provide the first signal to charge system 10. Accordingly, test module 106 does not receive electricity (i.e., at least for charging purposes) from charge system 100.

The fourth input mechanism can comprise a first setting (e.g., low) and a second setting (e.g., off). When the fourth input mechanism is set to the first setting (e.g., low), control module 107 can be configured to cause test module 106 to apply the first leakage current electric resistance to the electricity when charge system 10 provides the electricity to test module 106. Meanwhile, when the fourth input mechanism is set to the second setting (e.g., off), control module 107 can be configured not to cause test module 106 to apply the first leakage current electric resistance. In many embodiments, as described above, the fourth input mechanism can be configured to operate only when the first input mechanism is set to the second setting (e.g., manual).

The fifth input mechanism can comprise a first setting (e.g., high) and a second setting (e.g., off). When the fifth input mechanism is set to the first setting (e.g., high), control module 107 can be configured to cause test module 106 to apply the second leakage current electric resistance to the electricity when charge system 10 provides the electricity to test module 106. Meanwhile, when the fifth input mechanism is set to the second setting (e.g., off), control module 107 can be configured not to cause test module 106 to apply the first leakage current electric resistance. In many embodiments, the fifth input mechanism can be configured to operate only when the first input mechanism is set to the second setting (e.g., manual).

One having ordinary skill in the art can appreciate that any of the first input mechanism, the fourth input mechanism, and/or the fifth input mechanism may not operate as described above unless the second input mechanism is set to the first setting and/or the third input mechanism is set to the first setting (i.e., causing charge system 10 to provide the electricity to test module 106).

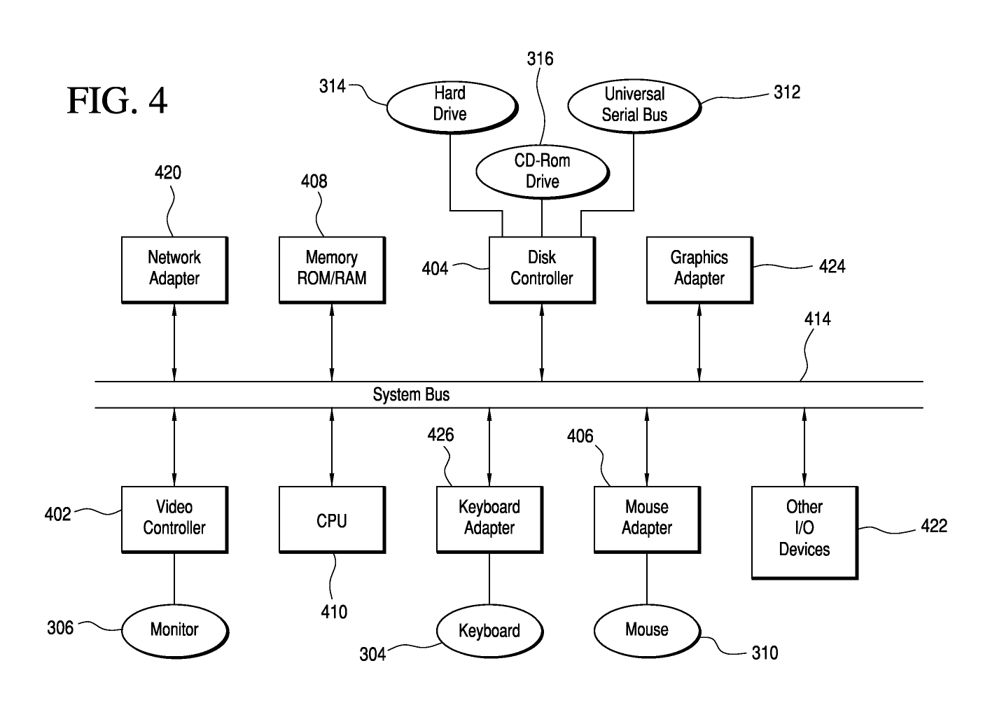

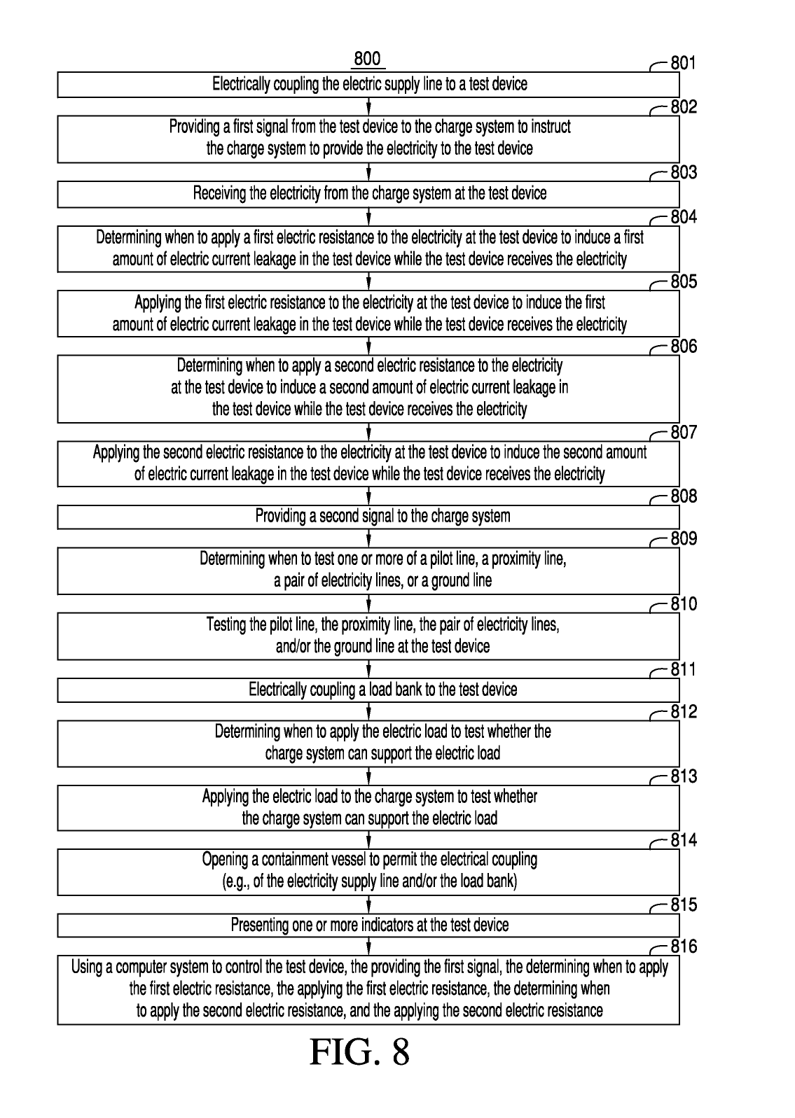

Returning now to the drawings, FIG. 3 illustrates an exemplary embodiment of computer system 300 that can be suitable for implementing an embodiment of input module 113, the operator computer system and/or the cloud computer system(s) described above with respect to input module 113, and/or at least part of test device 100 (FIG. 1) and/or method 800 (FIG. 8). Computer system 300 includes chassis 302 containing one or more circuit boards (not shown), Universal Serial Bus (USB) 312, Compact Disc Read-Only Memory (CD-ROM) and/or Digital Video Disc (DVD) drive 316, and hard drive 314. A representative block diagram of the elements included on the circuit boards inside chassis 302 is shown in FIG. 4. Central processing unit (CPU) 410 in FIG. 4 is coupled to system bus 414 in FIG. 4. In various embodiments, the architecture of CPU 410 can be compliant with any of a variety of commercially distributed architecture families.

System bus 414 also is coupled to memory 408, where memory 408 includes both read only memory (ROM) and random access memory (RAM). Non-volatile portions of memory 408 or the ROM can be encoded with a boot code sequence suitable for restoring computer system 300 (FIG. 3) to a functional state after a system reset. In addition, memory 408 can include microcode such as a Basic Input-Output System (BIOS). In some examples, the one or more storage modules of the various embodiments disclosed herein can include memory 408, USB 312 (FIGS. 3-4), hard drive 314 (FIGS. 3-4), and/or CD-ROM or DVD drive 316 (FIGS. 3-4). In the same or different examples, the one or more storage modules of the various embodiments disclosed herein can comprise an operating system, which can be a software program that manages the hardware and software resources of a computer and/or a computer network. The operating system can perform basic tasks such as, for example, controlling and allocating memory, prioritizing the processing of instructions, controlling input and output devices, facilitating networking, and managing files. Examples of common operating systems can include Microsoft® Windows, Mac® operating system (OS), UNIX® OS, and Linux® OS.

As used herein, “processor” and/or “processing module” means any type of computational circuit, such as but not limited to a microprocessor, a microcontroller, a controller, a complex instruction set computing (CISC) microprocessor, a reduced instruction set computing (RISC) microprocessor, a very long instruction word (VLIW) microprocessor, a graphics processor, a digital signal processor, or any other type of processor or processing circuit capable of performing the desired functions.

In the depicted embodiment of FIG. 4, various I/O devices such as disk controller 404, graphics adapter 424, video controller 402, keyboard adapter 426, mouse adapter 406, network adapter 420, and other I/O devices 422 can be coupled to system bus 414. Keyboard adapter 426 and mouse adapter 406 are coupled to keyboard 304 (FIGS. 3-4) and mouse 310 (FIGS. 3-4), respectively, of computer system 300 (FIG. 3). While graphics adapter 424 and video controller 402 are indicated as distinct units in FIG. 4, video controller 402 can be integrated into graphics adapter 424, or vice versa in other embodiments. Video controller 402 is suitable for refreshing monitor 306 (FIGS. 3-4) to display images on a screen 308 (FIG. 3) of computer system 300 (FIG. 3). Disk controller 404 can control hard drive 314 (FIGS. 3-4), USB 312 (FIGS. 3-4), and CD-ROM drive 316 (FIGS. 3-4). In other embodiments, distinct units can be used to control each of these devices separately.

In some embodiments, network adapter 420 can be part of a WNIC (wireless network interface controller) card (not shown) plugged or coupled to an expansion port (not shown) in computer system 300 (FIG. 3). In other embodiments, the WNIC card can be a wireless network card built into computer system 300 (FIG. 3). A wireless network adapter can be built into computer system 300 (FIG. 3) by having wireless Ethernet capabilities integrated into the motherboard chipset (not shown), or implemented via a dedicated wireless Ethernet chip (not shown), connected through the PCI (peripheral component interconnector) or a PCI express bus. In other embodiments, network adapter 420 can be a wired network adapter.

Although many other components of computer system 300 (FIG. 3) are not shown, such components and their interconnection are well known to those of ordinary skill in the art. Accordingly, further details concerning the construction and composition of computer system 300 (FIG. 3) and the circuit boards inside chassis 302 (FIG. 3) are not discussed herein.

When computer system 300 in FIG. 3 is running, program instructions stored on a USB-equipped electronic device connected to USB 312, on a CD-ROM or DVD in CD-ROM and/or DVD drive 316, on hard drive 314, or in memory 408 (FIG. 4) are executed by CPU 410 (FIG. 4). A portion of the program instructions, stored on these devices, can be suitable for carrying out at least part of method 800 (FIG. 8) and implementing one or more components of system 100 (FIG. 1).

Although computer system 300 (FIG. 3) is illustrated as a desktop computer in FIG. 3, there can be examples where computer system 300 may take a different form factor (e.g., a laptop computer, etc) while still having functional elements similar to those described for computer system 300. In some embodiments, computer system 300 may comprise a single computer, a single server, or a cluster or collection of computers or servers, or a cloud of computers or servers.

Returning now to FIG. 1, control module 107 can comprise indicator module 112. Indicator module 112 can be configured to indicate a device status of the test device and/or a test result of the test device. In some embodiments, indicator module can comprise one or more indicator mechanisms (e.g., labeled light emitting diodes) configured to indicate the device status of the test device and/or the test result of the test device. The one or more indicator mechanisms can comprise a pass indicator, a fail indicator, an electric fault indicator, a ground fault indicator, a proximity fault indicator, and a pilot fault indicator. In some embodiments, indicator module 112 can be configured to operate when the first input mechanism of input module 113 is set to the first setting. In the same or different embodiments, indicator module 112 can be configured to be deactivated when the first input mechanism of input module 113 is set to the second setting.

For example, the pass indicator can be configured to emit a flashing light after test module 106 tests one or more of pilot line 201 (FIG. 2), proximity line 202 (FIG. 2), electric lines 203 (FIG. 2), and/or ground line 206 (FIG. 2) if test device 100 detects no errors. Meanwhile, the pass indicator can be configured to emit a steady light after test module 106 applies the electric load of load bank 110 to charge system 10 to test if charge system 10 can support the electric load if test device 100 detects no errors.

The fail indicator can be configured to emit a flashing light while test module 106 tests one or more of pilot line 201 (FIG. 2), proximity line 202 (FIG. 2), electric lines 203 (FIG. 2), and/or ground line 206 (FIG. 2) and/or while test module 106 applies the electric load of load bank 110 to charge system 10 to test if charge system 10 can support the electric load. Meanwhile, the fail indicator can be configured to emit a steady light if test device 100 detects an error in one or more of pilot line 201, proximity line 202, electric lines 203, and/or ground line 206, as applicable, while or after test module 106 tests one or more of pilot line 201, proximity line 202, electric lines 203, and/or ground line 206. Accordingly, one or more of the pilot fault indicator, the proximity fault indicator, the electric fault indicator, and/or the ground fault indicator can be configured to emit a steady light to indicate an error in the corresponding line.

For example, test device 100 and/or indicator module 112 can indicate an error at pilot line 201 (FIG. 2) (e.g., via the pilot fault indicator) when pilot line 201 is improperly electrically coupled to the terminal block and/or the controlling circuit board of charge system 10. Test device 100 and/or indicator module 112 can indicate an error at proximity line 202 (FIG. 2) (e.g., via the proximity fault indicator) when proximity line 202 has failed, indicating that proximity line 202 needs to be replaced. Test device 100 and/or indicator module 112 can indicate an error at the electric grid line and/or when electric lines 203 (FIG. 2) (e.g., via the electric fault indicator) when the electric grid line is improperly electrically coupled to the terminal block and/or electric lines 203 are improperly electrically coupled to the contactor of charge system 10. Test device 100 and/or indicator module 112 can indicate an error at ground line 206 (FIG. 2), the control circuitry ground line, and/or the grid ground line (e.g., via the ground fault indicator) when ground line 206, the control circuitry ground line, and/or the grid ground line is/are improperly electrically coupled to the metal enfoldment of charge system 10.

Referring again to FIG. 1, in some embodiments, test device 100 can comprise containment vessel 111. Containment vessel 111 can enclose test module 106 and/or control module 107. Containment vessel 111 can comprise a container configured to be impermeable to water and air (i.e., hermetically sealed) when closed. In some embodiments, containment vessel 111 can comprise a Pelican™ case, manufactured by Pelican Products, Incorporated of Torrance, Calif.

In many embodiments, test device 10 and/or containment vessel 111 can be portable and/or ruggedized. For example, test device 10 can weigh greater than or equal to approximately 5 pounds (2.26 kilograms) and less than or equal to approximately 25 pounds (11.34 kilograms). Meanwhile, test device 10 and/or containment vessel 111 can occupy a volume less than or equal to approximately 4096 cubic inches (67122 cubic centimeters) (e.g., approximately 16 inches (40.64 centimeters) in length, width, and height).

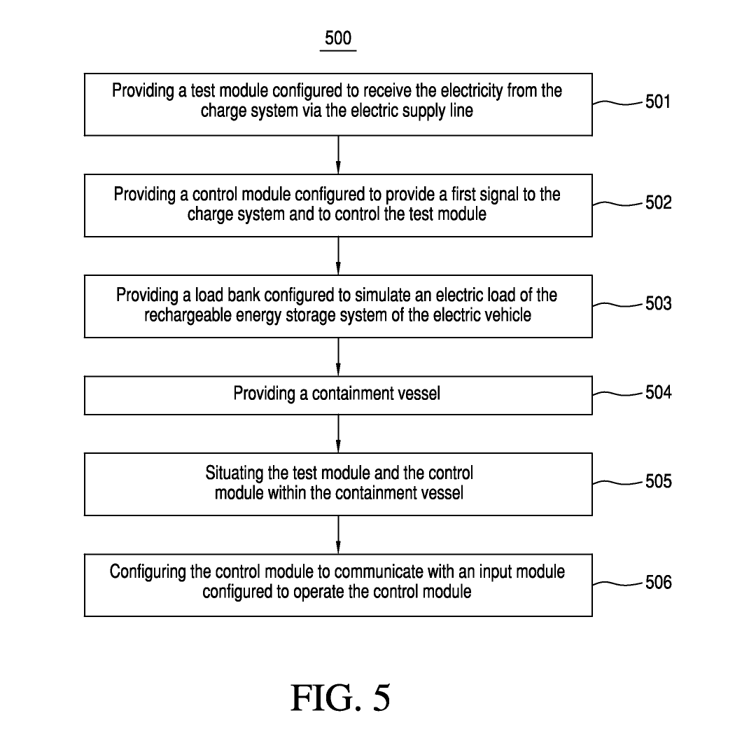

FIG. 5 illustrates a flow chart for an embodiment of method 500 of providing a test device for testing a charge system. The test device can be similar or identical to test device 100 (FIG. 1) and/or the charge system can be similar or identical to charge system 10 (FIG. 1). The charge system can be configured to provide electricity to charge a rechargeable energy storage system of an electric vehicle via an electric supply line. The electric supply line can be similar or identical to electric supply line 40 (FIG. 1). Likewise, the rechargeable energy storage system and/or the electric vehicle can be similar or identical to the rechargeable energy storage system and/or the electric vehicle, respectively, as described above with respect to test device 100 (FIG. 1). Method 500 is merely exemplary and is not limited to the embodiments presented herein. Method 500 can be employed in many different embodiments or examples not specifically depicted or described herein. In some embodiments, the procedures, the processes, and/or the activities of method 500 can be performed in the order presented. In other embodiments, the procedures, the processes, and/or the activities of the method 500 can be performed in any other suitable order. In still other embodiments, one or more of the procedures, the processes, and/or the activities in method 500 can be combined or skipped.

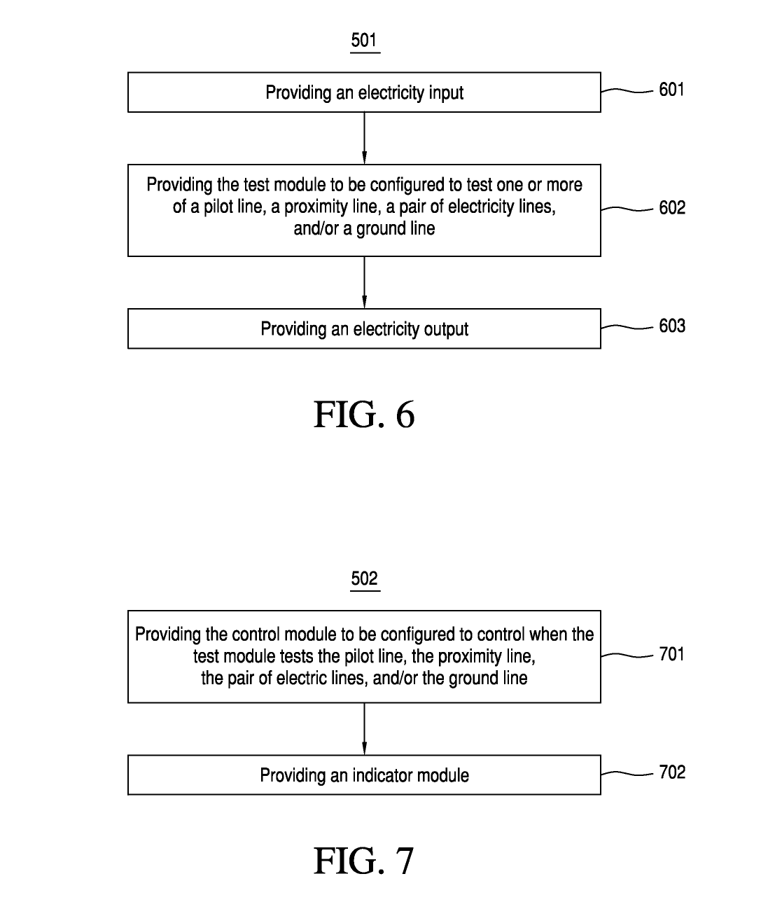

Referring now to FIG. 5, method 500 comprises procedure 501 of providing a test module configured to receive the electricity from the charge system via the electric supply line. The test module can be similar or identical to test module 106 (FIG. 1). FIG. 6 illustrates a flow chart for an exemplary embodiment of procedure 501, according to an embodiment of method 500.

Referring now to FIG. 6, procedure 501 can comprise process 601 of providing an electricity input. The electricity input can be similar or identical to electricity input 108 (FIG. 1).

Next, referring again to FIG. 6, procedure 501 can comprise process 602 of providing the test module to be configured to test one or more of a pilot line, a proximity line, a pair of electric lines, and/or a ground line. In various embodiments, the pilot line can be similar or identical to pilot line 201 (FIG. 2), the proximity line can be similar or identical to proximity line 202 (FIG. 2), the electric lines can be similar or identical to electric lines 203 (FIG. 2), and/or the ground line can be similar or identical to ground line 206 (FIG. 2).

Then, referring again to FIG. 6, procedure 501 can comprise process 603 of providing an electricity output. The electricity output can be similar or identical to electricity output 109 (FIG. 1).

Referring back to FIG. 5, method 500 can continue with procedure 502 of providing a control module configured to provide a first signal to the charge system and to control the test module. The control module can be similar or identical to control module 107 (FIG. 1). The first signal can be similar or identical to the first signal described above with respect to test device 100 (FIG. 1). FIG. 7 illustrates a flow chart for an exemplary embodiment of procedure 502, according to an embodiment of method 500.

Referring now to FIG. 7, procedure 502 can comprise process 701 of providing the control module to be configured to control when the test module tests the pilot line, the proximity line, the pair of electric lines, and/or the ground line.

Referring again to FIG. 7, procedure 503 can also comprise process 702 of providing an indicator module. The indicator module can be similar or identical to indicator module 112 (FIG. 1).

Referring back to FIG. 5, in some embodiments, method 500 can continue with procedure 503 of providing a load bank configured to simulate an electric load of the electric system of the electric vehicle. The load bank can be similar or identical to load bank 110 (FIG. 1).

Referring again to FIG. 5, in various embodiments, method 500 can also comprise procedure 504 of providing a containment vessel. The containment vessel can be similar or identical to containment vessel 111 (FIG. 1). In some embodiments, procedures 501-504 can occur in any sequence, and/or can occur approximately simultaneously with each other. Then, method 500 can continue with procedure 505 of situating the test module and the control module within the containment vessel. If procedure 504 is omitted from method 500, so too is procedure 505.

Referring again to FIG. 5, method 500 can comprise procedure 506 of configuring the control module to communicate with an input module configured to operate the control module. The input module can be similar or identical to input module 113 (FIG. 1). In some embodiments, procedure 506 can occur before or after procedure 505.

Turning to the last figure, FIG. 8 illustrates a flow chart for an embodiment of a method 800 of testing a charge system. The charge system can be similar or identical to charge system 10 (FIG. 1). The charge system can be configured to provide electricity to charge a rechargeable energy storage system of an electric vehicle via an electric supply line. The electric supply line can be similar or identical to electric supply line 40 (FIG. 1). Likewise, the rechargeable energy storage system and/or the electric vehicle can be similar or identical to the rechargeable energy storage system and/or the electric vehicle, respectively, as described above with respect to test device 100 (FIG. 1). In some embodiments, at least part of method 800 can be implemented via execution of computer instructions configured to run at one or more processing modules and configured to be stored at one or more storage modules. Method 800 is merely exemplary and is not limited to the embodiments presented herein. Method 800 can be employed in many different embodiments or examples not specifically depicted or described herein. In some embodiments, the procedures, the processes, and/or the activities of method 800 can be performed in the order presented. In other embodiments, the procedures, the processes, and/or the activities of the method 800 can be performed in any other suitable order. In still other embodiments, one or more of the procedures, the processes, and/or the activities in method 800 can be combined or skipped.

Referring now to FIG. 8, method 800 comprises procedure 801 of electrically coupling the electric supply line to a test device. The test device can be similar or identical to test device 100 (FIG. 1).

Referring again to FIG. 8, method 800 can comprise procedure 802 of providing a first signal from the test device to the charge system to instruct the charge system to provide the electricity to the test device. The first signal can be similar or identical to the first signal as described above with respect to test device 100 (FIG. 1). Procedure 802 can comprise providing a first signal from a control module of the test device to the charge system to instruct the charge system to provide the electricity to the test device. The control module can be similar or identical to control module 107 (FIG. 1).

Referring again to FIG. 8, method 800 comprises procedure 803 of receiving the electricity from the charge system at the test device. Procedure 803 can be performed and/or can occur after procedure 802 is performed and/or occurs.

Referring again to FIG. 8, method 800 can comprise procedure 804 of determining when to apply a first electric resistance to the electricity at the test device to induce a first amount of electric current leakage in the test device while the test device receives the electricity.

Referring again to FIG. 8, method 800 comprises procedure 805 of applying the first electric resistance to the electricity at the test device to induce the first amount of electric current leakage in the test device while the test device receives the electricity. In some embodiments, procedure 805 can comprise using an input module of the control module, at the control module, and/or in communication with the control module to apply the first electric resistance to the electricity at the test device to induce the first amount of electric current leakage in the test device while the test device receives the electricity. The input module can be similar or identical to input module 113 (FIG. 1). In many embodiments, procedure 804 and procedure 805 can be performed and/or can occur approximately simultaneously.

Referring again to FIG. 8, method 800 can comprise procedure 806 of determining when to apply a second electric resistance to the electricity at the test device to induce a second amount of electric current leakage in the test device while the test device receives the electricity. The second amount of electric current leakage can exceed the first amount of electric current leakage.

Referring again to FIG. 8, method 800 comprises procedure 807 of applying the second electric resistance to the electricity at the test device to induce the second amount of electric current leakage in the test device while the test device receives the electricity. In some embodiments, procedure 807 can comprise using the input module to apply the second electric resistance to the electricity at the test device to induce the second amount of electric current leakage in the test device while the test device receives the electricity. In many embodiments, procedure 807 can comprise activating a residual current device of the charge system. The residual current device can be similar or identical to residual current device 50 (FIG. 1). In the same or different embodiments, the first amount of electric current leakage can be insufficient to activate the residual current device. In many embodiments, procedure 806 and procedure 807 can be performed and/or can occur approximately simultaneously.

Referring again to FIG. 8, method 800 can comprise procedure 808 of providing a second signal to the charge system. The second signal can be similar or identical to the second signal described above with respect to test device 100 (FIG. 1). Procedure 808 can be performed and/or can occur before, after, or while procedure 801 is performed and/or occurs.

Referring again to FIG. 8, method 800 can comprise procedure 809 of determining when to test one or more of a pilot line, a proximity line, a pair of electric lines, or a ground line. In various embodiments, the pilot line can be similar or identical to pilot line 201 (FIG. 2), the proximity line can be similar or identical to proximity line 202 (FIG. 2), the electric lines can be similar or identical to electric lines 203 (FIG. 2), and/or the ground line can be similar or identical to ground line 206 (FIG. 2). Method 800 can comprise procedure 810 of testing the pilot line, the proximity line, the pair of electric lines, and/or the ground line at the test device. When procedure 809 is omitted from method 800, so too can be procedure 810, or vice versa.

Referring again to FIG. 8, method 800 can comprise procedure 811 of electrically coupling a load bank to the test device. The load bank can be similar or identical to load bank 110 (FIG. 1).

Referring again to FIG. 8, method 800 can comprise procedure 812 of determining when to apply the electric load to test whether the charge system can support the electric load.

Referring again to FIG. 8, method 800 can comprise procedure 813 of applying the electric load to the charge system to test whether the charge system can support the electric load. In many embodiments, procedure 812 and procedure 813 can be performed and/or can occur approximately simultaneously.

Referring again to FIG. 8, method 800 can comprise procedure 814 of opening a containment vessel to permit the electrical coupling (e.g., of the electric supply line and/or the load bank). The containment vessel can be similar or identical to containment vessel 111 (FIG. 1). Procedure 814 can be performed and/or can occur before procedure 801 is performed and/or occurs.

Referring again to FIG. 8, method 800 can comprise procedure 815 of presenting one or more indicators at the test device. The one or more indicators can be similar or identical to the one or more indicator mechanisms described above with respect to test device 100 (FIG. 1).

Referring again to FIG. 8, method 800 can comprise procedure 816 of using an operator computer system and/or an application programmable interface to control the test device, the providing the first signal, the determining when to apply the first electric resistance, the applying the first resistance, the determining when to apply the second electric resistance, and the applying the second electric resistance. The operator computer system can be similar or identical to the operator computer system described above with respect to test device 100 (FIG. 1) and/or computer system 300 (FIG. 3). Further, the application programmable interface can be similar or identical to the application programmable interface described above with respect to test device 100 (FIG. 1). Accordingly, in some embodiments, the input module can comprise the operator computer system and/or the application programmable interface. In some embodiments, procedure 816 can be omitted. In other embodiments, procedure 816 occurs during the performance and/or occurrence of one or more of procedures 802, 804-810, 812-813, and/or 815.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that procedures 501-506 of FIG. 5, processes 601-603 of FIG. 6, processes 701-702 of FIG. 7, and procedures 801-816 of FIG. 8 may be comprised of many different procedures, processes, and activities and be performed by many different modules, in many different orders, that any element of FIGS. 1-8 may be modified, and that the foregoing discussion of certain of these embodiments does not necessarily represent a complete description of all possible embodiments.

All elements claimed in any particular claim are essential to the embodiment claimed in that particular claim. Consequently, replacement of one or more claimed elements constitutes reconstruction and not repair. Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims, unless such benefits, advantages, solutions, or elements are expressly stated in such claim.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A test device for testing a charge system, the charge system being configured to provide electricity to charge a rechargeable energy storage system of an electric vehicle via an electric supply line and the charge system comprising a residual current device, the test device comprising:
a test module configured to receive the electricity from the charge system via the electric supply line; and
a control module configured to provide a first signal to the charge system and to control the test module;
wherein:
the test module is configured to be electrically coupled to the charge system via the electric supply line;
the first signal is configured to instruct the charge system to provide the electricity to the test module;
the test module is configured to apply a first electric resistance to the electricity to induce a first amount of electric current leakage in the test device while the charge system provides the electricity to the test module;
the test module is configured to apply a second electric resistance to the electricity to induce a second amount of electric current leakage in the test device while the charge system provides the electricity to the test module;
the second amount of electric current leakage exceeds the first amount of electric current leakage;
the control module is configured to control when the test module applies the first electric resistance and the second electric resistance to test the residual current device; and
the test device is configured to emulate the rechargeable energy storage system of the electric vehicle.

2. The test device of claim 1 wherein:
the first amount of electric current leakage is insufficient to activate the residual current device; and
the second amount of electric current leakage is sufficient to activate the residual current device.

3. The test device of claim 1 wherein:
the test module comprises an electricity input;
the electricity input comprises an electrical receptacle for a Society of Automotive Engineers J1772 electrical connector;
the electric supply line comprises the Society of Automotive Engineers J1772 electrical connector; and
the electrical receptacle is configured to receive the Society of Automotive Engineers J1772 electrical connector to electrically couple the test module to the charge system via the electric supply line.

4. The test device of claim 1 wherein:
the electric supply line comprises at least one of a pilot line, a proximity line, a pair of electric lines, or a ground line;
the test module is configured to test one or more of the at least one of the pilot line, the proximity line, the pair of electric lines, or the ground line while the charge system provides the electricity to the test module; and
the control module is configured to control when the test module tests the one or more of the at least one of the pilot line, the proximity line, the pair of electric lines, or the ground line.

5. The test device of claim 1 wherein:
the control module is configured to provide a second signal to the charge system before providing the first signal to the charge system; and
the second signal is configured to notify the charge system that the test module is electrically coupled to the charge system via the electric supply line.

6. The test device of claim 1 wherein:
the test module comprises an electricity output; and
the electricity output comprises an electrical receptacle for a National Electrical Manufacturers Association 14-50 electrical connector.

7. The test device of claim 6 further comprising:
a load bank configured to simulate an electric load of the rechargeable energy storage system of the electric vehicle;
wherein:
the test module is configured to be electrically coupled with the load bank via the electricity output;
the test module is configured to apply the electric load to the charge system; and
the control module is configured to control when the test module applies the electric load to the charge system in order to test whether the charge system can support the electric load.

8. The test device of claim 1 further comprising:
a containment vessel enclosing the test module and the control module.

9. The test device of claim 1 wherein:
the control module comprises an indicator module; and
the indicator module is configured to indicate at least one of a device status of the test device or a test result of the test device.

10. The test device of claim 1 wherein:
the control module is configured to communicate with an input module configured to operate the control module.

11. The test device of claim 10 wherein:
the control module comprises the input module.

12. The test device of claim 10 wherein:
the input module is separate from the test device; and
the input module comprises a computer system.

13. The test device of claim 1 further comprising:
a containment vessel enclosing the test module and the control module.
wherein:
the test device is portable;
the test module comprises an electricity input;
the electricity input comprises an electrical receptacle for a Society of Automotive Engineers J1772 electrical connector;
the electric supply line comprises the Society of Automotive Engineers J1772 electrical connector;
the electrical receptacle is configured to receive the Society of Automotive Engineers J1772 electrical connector to electrically couple the test module to the charge system via the electric supply line;
the electric supply line comprises a pilot line, a proximity line, a pair of electric lines, and a ground line;
the test module is configured to test each of the pilot line, the proximity line, the pair of electric lines, and the ground line;
the control module is configured to control when the test module tests each of the pilot line, the proximity line, the pair of electric lines, and the ground line;
the control module is configured to provide a second signal to the charge system before providing the first signal to the charge system;
the second signal is configured to notify the charge system that the test module is electrically coupled to the charge system via the electric supply line;
the test module comprises an electricity output;
the electricity output comprises an electrical receptacle for a National Electrical Manufacturers Association 14-50 electrical connector;
the test module is configured to be electrically coupled with a load bank via the electricity output, the load bank being configured to simulate an electric load of the rechargeable energy storage system of the electric vehicle;
the test module is configured to apply the electric load to the charge system;
the control module is configured to control when the test module applies the electric load to the charge system in order to test whether the charge system can support the electric load;
the control module comprises an indicator module;
the indicator module is configured to indicate at least one of a device status of the test device or a test result of the test device;
the control module is configured to communicate with an input module configured to operate the control module; and
the control module comprises the input module.

14. A method of providing a test device for testing a charge system, the charge system being configured to provide electricity to charge a rechargeable energy storage system of an electric vehicle via an electric supply line and the charge system comprising a residual current device, the method comprising:
providing a test module configured to receive the electricity from the rechargeable energy storage system via the electric supply line; and
providing a control module configured to provide a first signal to the charge system and to control the test module;
wherein:
the test module is configured to be electrically coupled to the charge system via the electric supply line;
the first signal is configured to instruct the charge system to provide the electricity to the test module;
the test module is configured to apply a first electric resistance to the electricity to induce a first amount of electric current leakage in the test device while the charge system provides the electricity to the test module;
the test module is configured to apply a second electric resistance to the electricity to induce a second amount of electric current leakage in the test device while the charge system provides the electricity to the test module;
the second amount of electric current leakage exceeds the first amount of electric current leakage;
the control module is configured to control when the test module applies the first electric resistance and the second electric resistance to test the residual current device; and
the test device is configured to emulate the rechargeable energy storage system of the electric vehicle.

15. The method of claim 14 wherein:
providing the test module comprises providing an electricity input;
the electricity input comprises an electrical receptacle for a Society of Automotive Engineers J1772 electrical connector;
the electric supply line comprises the Society of Automotive Engineers J1772 electrical connector; and
the electrical receptacle is configured to receive the Society of Automotive Engineers J1772 electrical connector to electrically couple the test module to the charge system via the electric supply line.

16. The method of claim 14 wherein:
the electric supply line comprises at least one of a pilot line, a proximity line, a pair of electric lines, or a ground line;
providing the test module comprises providing the test module to be configured to test one or more of the at least one of the pilot line, the proximity line, the pair of electric lines, or the ground line; and
providing the control module comprises providing the control module to be configured to control when the test module tests the one or more of the at least one of the pilot line, the proximity line, the pair of electric lines, or the ground line.

17. The method of claim 14 wherein:
providing the test module comprises providing an electricity output; and
the electricity output comprises an electrical receptacle for a National Electrical Manufacturers Association 14-50 electrical connector.

18. The method of claim 17 further comprising:
providing a load bank configured to simulate an electric load of the rechargeable energy storage system of the electric vehicle;
wherein:
the test module is configured to be electrically coupled with the load bank via the electricity output;
the test module is configured to apply the electric load to the charge system; and
the control module is configured to control when the test module applies the electric load to the charge system in order to test whether the charge system can support the electric load.

19. The method of claim 14 further comprising:
providing a containment vessel; and
situating the test module and the control module within the containment vessel.

20. The method of claim 14 wherein:
providing the control module comprises providing an indicator module; and
the indicator module is configured to indicate at least one of a device status of the test device or a test result of the test device.

21. The method of claim 14 further comprising:
configuring the control module to communicate with an input module configured to operate the control module.

22. A method of testing a charge system, the charge system being configured to provide electricity to charge a rechargeable energy storage system of an electric vehicle via an electric supply line and the charge system comprising a residual current device, the method comprising:
electrically coupling the electric supply line to a test device, the test device being configured to receive the electricity from the charge system via the electric supply line and being configured to emulate the rechargeable energy storage system of the electric vehicle;
providing a first signal from the test device to the charge system to instruct the charge system to provide the electricity to the test device;
after providing the first signal, receiving the electricity from the charge system at the test device;
determining when to apply a first electric resistance to the electricity at the test device to induce a first amount of electric current leakage in the test device while the test device receives the electricity;
applying the first electric resistance to the electricity at the test device to induce the first amount of electric current leakage in the test device while the test device receives the electricity;
determining when to apply a second electric resistance to the electricity at the test device to induce a second amount of electric current leakage in the test device while the test device receives the electricity, the second amount of electric current leakage exceeding the first amount of electric current leakage; and
applying the second electric resistance to the electricity at the test device to induce the second amount of electric current leakage in the test device while the test device receives the electricity.

23. The method of claim 22 wherein:
applying the second electric resistance comprises activating the residual current device; and
the first amount of electric current leakage is insufficient to activate the residual current device.

24. The method of claim 22 further comprising:
after electrically coupling the electric supply line to the test device and before providing the first signal to the charge system, providing a second signal to the charge system, the second signal being configured to notify the charge system that the test device is electrically coupled to the electric supply line.

25. The method of claim 22 wherein:
the electric supply line comprises at least one of a pilot line, a proximity line, a pair of electric lines, or a ground line; and
the method further comprises:
determining when to test one or more of the at least one of the pilot line, the proximity line, the pair of electric lines, or the ground line; and
testing the one or more of the at least one of the pilot line, the proximity line, the pair of electric lines, or the ground line at the test device.

26. The method of claim 22 further comprising:
electrically coupling a load bank to the test device, the load bank being configured to simulate an electric load of the rechargeable energy storage system of the electric vehicle;
determining when to apply the electric load to test whether the charge system can support the electric load; and
applying the electric load to the charge system to test whether the charge system can support the electric load.

27. The method of claim 22 further comprising:
before electrically coupling the electric supply line to the test device, opening a containment vessel to permit the electrical coupling.

28. The method of claim 22 further comprising:
presenting one or more indicators at the test device, the one or more indicators being configured to indicate at least one of a device status of the test device or a test result of the test device.

29. The method of claim 22 further comprising:
using a computer system to control the test device, the providing the first signal, the determining when to apply the first electric resistance, the applying the first electric resistance, the determining when to apply the second electric resistance, and the applying the second electric resistance.
